(19) United States
(12) Patent Application Publication
(10) Pub. No.: US 2004/0107565 A1
(43) Pub. Date: Jun. 10, 2004

(54) Fixture for assembling an inductor

(75) Inventors: Shou-Kuen Chou, (US); Ming-Tung Lai, (US)

Correspondence Address: John G. Chupa, Law Offices of John Chupa & Associates, P.C., 28535 Orchard Lake Rd., Ste. 50, Farmington Hills, MI, 48334, US

(73) Assignee: FERRICO CORPORATION

(21) Appl. No.: 10/358,885

(22) Filed: Feb. 5, 2003

(30) Foreign Application Priority Data
Dec. 10, 2002 (TW) 091219972

(51) Int. Cl. B23P 19/00; H05K 3/34

(52) U.S. Cl. 29/739; 29/737; 29/602.1; 29/840

(57) ABSTRACT

A fixture for assembling an inductor is a flat locating seat with an upper side thereof having a locating nest corresponding to the RI core of the inductor and having a central part corresponding to a locating part disposed at the bottom of the DR core in the inductor. The inductor can be located at the fixture and operations such as soldering and spot gluing can be performed steadily.

### BACKGROUND OF THE INVENTION

1. Field of the Invention

The present invention relates to a fixture for assembling an inductor.

2. Description of Related Art

The inductor usually has a coiled DR core and a covering RI, core and the DR core at both coil ends thereof is soldered to the RI core respectively so that the DR core can be connected to the RI core. The RI core has open upper and lower ends for the DR core being possible to be placed and located therein.

The inductor has a very small size and it can be fabricated with automation, which is a more advanced way. However, the equipment for the automation is very expensive so that it is lack of economic effectiveness if the output is under an economic scale. Therefore, it is sill adopted in many factories that the inductor is assembled manually with a fixture.

As the foregoing, the inductor is tiny in the volume thereof and it is very difficult to be assembled especially at the time of being located, soldered and spot gluing. Hence, it is a subject worth us to investigate.

### SUMMARY OF THE INVENTION

The crux of the present invention is to provide a fixture for assembling an inductor, which is a flat locating seat with an upper side thereof having a locating nest corresponding to the RI core of the inductor and having a central part corresponding to a locating part disposed at the bottom of the DR core in the inductor.

The inductor can be located at the fixture and operations such as soldering and spot gluing can be performed steadily.

### BRIEF DESCRIPTION OF THE DRAWINGS

The present invention can be more fully understood by reference to the following description and accompanying drawings, in which:

FIG. 1 is an exploded perspective view of the present invention in a first embodiment thereof illustrating an inductor and a locating seat;

FIG. 2 is a perspective view illustrating the inductor being mounted with a fixture according to the present invention;

FIG. 3 is a perspective view illustrating a magnetic bar and a partition being added during assembling;

FIG. 4 is an exploded perspective view of the present invention in a second embodiment thereof; and

FIG. 5 is a perspective view of the second embodiment according to the present invention.

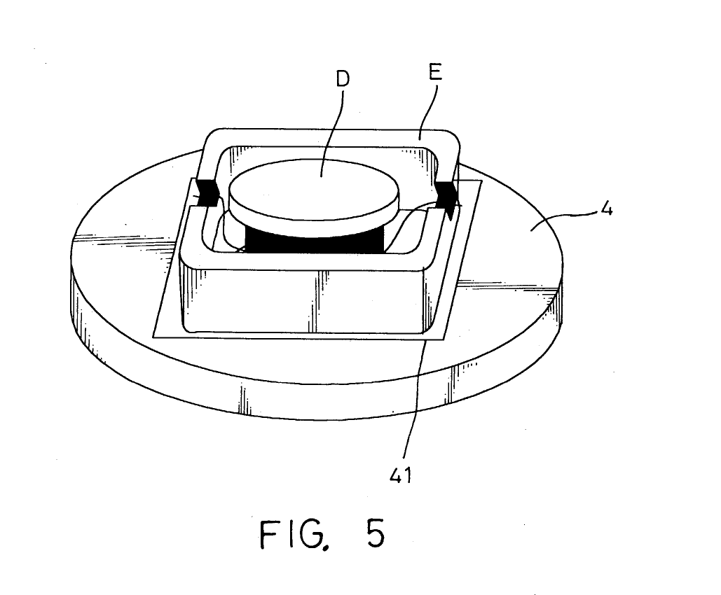

### DETAILED DESCRIPTION OF THE PREFERRED EMBODIMENT

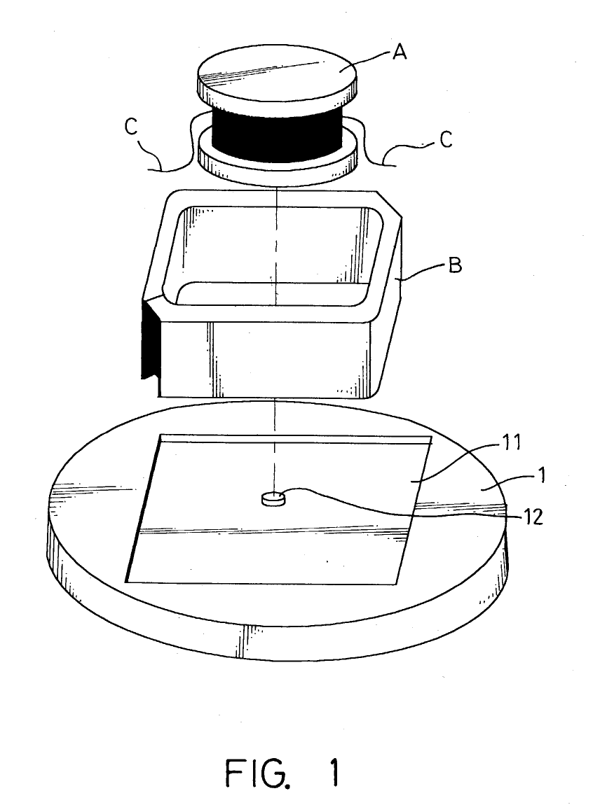

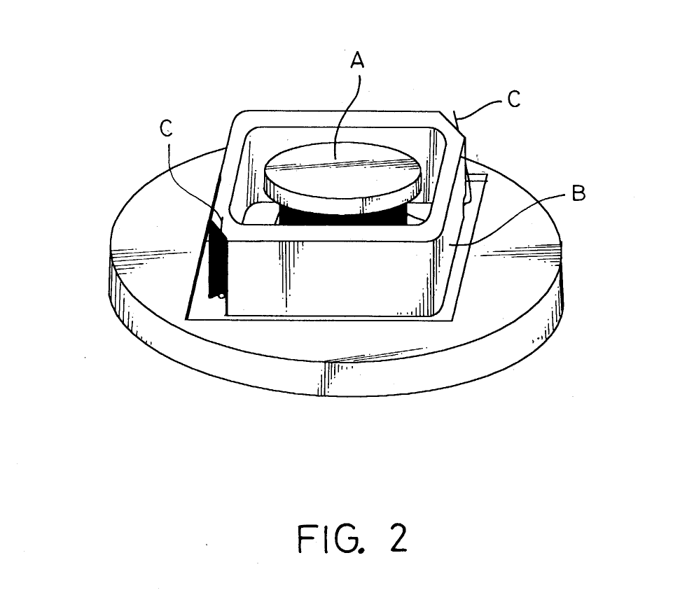

Referring to FIG. 1, basically, as the foregoing, the inductor is composed of a DR core A and a RI core B. After the finished products of DR core A and the RI core B being completed, the DR core A is placed in the RI core B and coil ends C of the DR core A are soldered to two diagonally opposite corners of the RI core B. Further, the RI core B is adhesively joined to the DR core A by way of spot gluing as shown in FIG. 2.

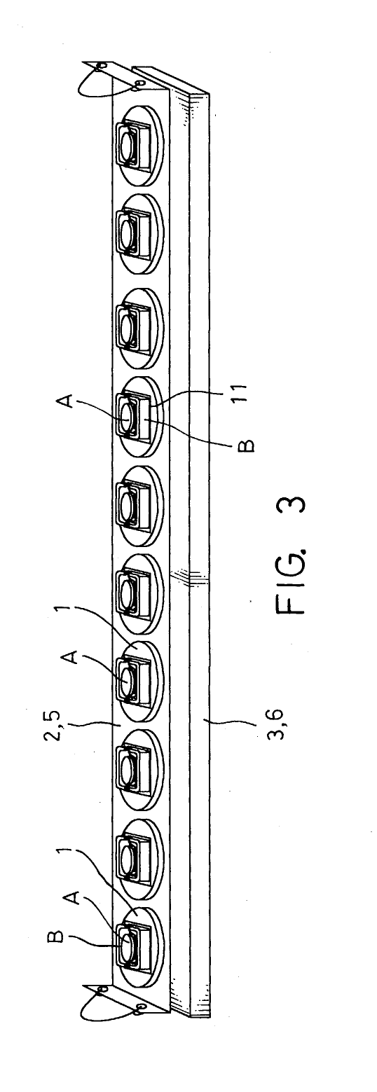

Therefore, in order to facilitate the assembling, referring to FIG. 3, a fixture of the present invention is disclosed and the fixture includes a locating seat 1, a partition 2 and a magnetic bar 3.

Wherein, the locating seat 1 is a flat piece and made of non-magnetized material, which preferably is ceramics, and in order to locate the DR core A and the RI core B, the upper side thereof is provided with a locating nest 11 and the locating nest 11 has a size corresponding to the outer edge of the RI core B so as to accommodate and locate the RI core B. Further, the locating seat 1 projects a central locating jut 12 corresponding to a central bottom hole of the DR core A so that the DR core A can be joined to the locating seat 1 by way of the locating jut 12 fitting with the bottom hole. FIG. 2 shows the DR core A, the RI core B and locating seat 1 have been put together by the fixture and, meanwhile, the operations of soldering and spot gluing can be performed to complete the assembly.

Further, in order to make operations of the spot gluing and the soldering much firmly, as shown in FIG. 3, a partition plate 2 is added so that the preceding located DR core A, the RI core B and the locating seat 1 can be placed on the partition plate 2. In addition, the magnetic bar 3 can be provided under the partition 2 and, in this way, the DR core A can keep in a state of being fixed through the magnetic attraction force. Hence, the assembling operation can be performed much steadily. Once all the soldering and the spot gluing operations are finished, the partition plate 2 is detached from the magnetic bar 3 so as to separate the assembled inductor from the locating seat 1.

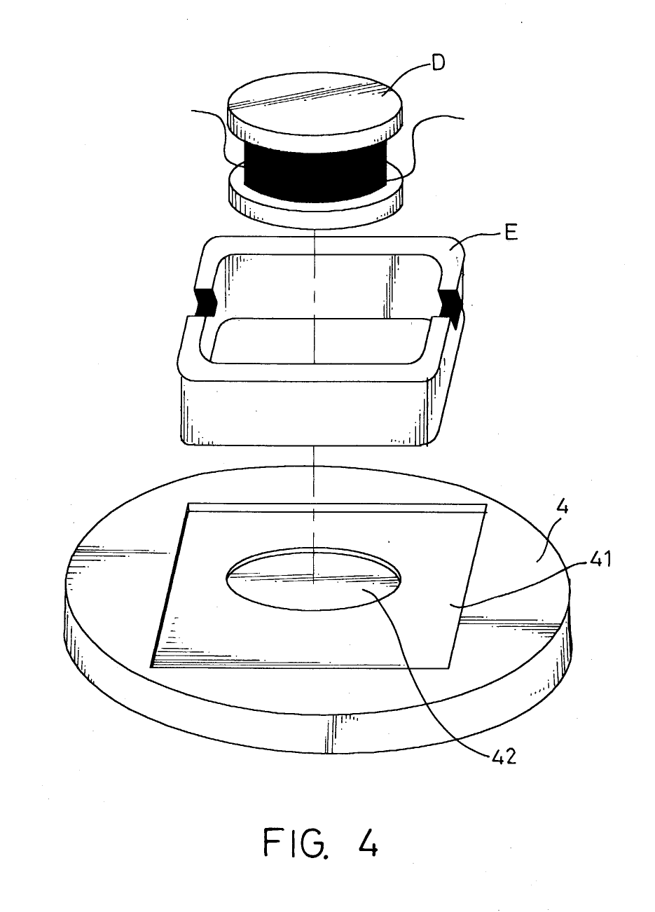

Referring to FIG. 4, the second embodiment of the present invention is illustrated. The DR core D at the bottom thereof does not provide a locating hole and the RI core E at two opposite side frames thereof has an upper soldering spot respectively. Meanwhile, a locating seat 4 at the central position thereof provides a recess corresponding to a locating hole 42 of the DR core D in addition to having a locating nest 42 corresponding to the RI core E such that DR core D and RI core can be located at the locating seat 4. The partition 5 and the magnetic bar 6 are the same as those in the first embodiment of the present invention.

It is appreciated that the fixture of the present invention can locate the inductor and make the operations of soldering and spot gluing simple so that it is much helpful for the production efficiency and the product quality.

While the invention has been described with reference to preferred embodiments thereof, it is to be understood that modifications or variations may be easily made without departing from the spirit of this invention, which is defined by the appended claims.

What is claimed is:

1. A fixture for assembling an inductor, being a flat locating seat, having an upper side with a locating nest corresponding to a RI core of the inductor and having a central part corresponding to a locating part disposed at a bottom of a DR core in the inductor;
whereby, the inductor can be located at the fixture and operations such as soldering and spot gluing can be performed steadily.

2. The fixture for assembling an inductor as defined in claim 1, wherein the locating part at the bottom of the DR core is a hole and the central part of the locating seat is a projecting jut.

3. The fixture for assembling an inductor as defined in claim 1, wherein the locating part at the bottom of the DR core is an outer edge of the bottom and the central part of the seating seat is a blind locating hole.

4. The fixture for assembling an inductor as defined in claim 1, wherein the locating seat is made of ceramics.

5. The fixture for assembling an inductor as defined in claim 1, wherein a partition can be added for receiving a plurality of locating seats and a magnetic bar is disposed under the partition to attract and locate the DR core.
